(19) United States
(12) Patent Application Publication
(10) Pub. No.: US 2009/0081880 A1
(43) Pub. Date: Mar. 26, 2009

(54) Method for manufacturing semiconductor device

(75) Inventor: Toru Yoshie, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/232,052

(22) Filed: Sep. 10, 2008

(30) Foreign Application Priority Data
Sep. 26, 2007 (JP) 2007-249781

(51) Int. Cl. H01L 21/302

(52) U.S. Cl. 438/745; 257/E21.249

(57) ABSTRACT

The present invention provides a method for manufacturing a semiconductor device includes: a immersion process of immersing, in a fluoronitric acid solution, a lamination substrate, in which an SiC substrate formed of a silicon carbide (SiC) single crystal is applied to a silicon substrate or a quarts substrate with a larger hole diameter than the SiC substrate; and a peeling process of taking out the SiC substrate which is not dissolved and remains in the fluoronitric acid solution after the silicon substrate or the quartz substrate is dissolved and removed from the fluoronitric acid solution.

### CROSS REFERENCE TO RELATED APPLICATION

This application claims the priority of Application No. 2007-249781, filed Sep. 26, 2007 in Japan, the subject matter of which is incorporated herein by reference.

### TECHNICAL FIELD OF THE INVENTION

The present invention relates to a method for manufacturing a semiconductor device, and especially relates to a method for manufacturing a semiconductor device (SiC device) using SiC crystal in which an SiC substrate formed of a silicon carbide (SiC) single crystal less likely to increase the hole diameter is applied to a silicon (Si) substrate with a hole diameter larger than the SiC substrate to be processed to a lamination substrate capable of being manufactured in an existing manufacture line, and, thus, to be subjected to various processings, and thereafter, the SiC substrate is peeled from the lamination substrate.

### BACKGROUND OF THE INVENTION

A semiconductor device (SiC device) using a silicon carbide crystal has such characteristics as high withstanding pressure and high temperature operation, in comparison with the conventional semiconductor device (Si device) using a silicon crystal. The SiC device shows such an excellent performance based on basic characteristics of SiC crystal. Carbon atoms are contained in the SiC crystal, whereby the distance between the atoms is reduced to realize the stronger coupling, and, thus, to increase the size of a band gap of a semiconductor twice or more. As a result, the withstanding pressure is increased to twice or more electric field, and the semiconductor characteristics are maintained until reaching a high temperature.

Although the SiC crystal has extremely excellent basic characteristics, the crystal growth is very difficult, and crystal defect is easily caused; therefore, there is a problem that the hole diameter of the substrate (wafer) is hard to be increased. At present, an Si substrate (Si wafer) with a hole diameter of 5 to 8 inch is mostly used, while a very expensive 4H—SiC substrate (SiC wafer) with a hole diameter of 2 to 3 inch is mostly used. Therefore, in carrying out development of the semiconductor device, the 4H—SiC substrate is often cut into small chips to carry out trial manufacture, and thus, it is very difficult to obtain basic data for mass production.

In the development of the mass production techniques in the SiC device, it is very effective to use a device group used in the manufacturing of the Si device. In addition, know-how in mass production techniques used for the manufacturing of the Si device can be effectively utilized. Currently, the SiC device can be miniaturized to about 0.5 μm in the latest technology, and therefore, the microfabriaction can be applied to the SiC device using an existing Si device manufacturing device.

However, as above mentioned, in the SiC crystal, only a substrate with a hole diameter of up to about 3 inch can be formed, and therefore, it is difficult to use an existing Si device manufacturing device. In order to use the Si device manufacturing device, Japanese Patent Application Laid-Open No. 11-87200 proposes that a semiconductor substrate in which an SiC substrate with a small hole diameter is applied with an Si substrate is processed in a similar manner to the Si substrate with a larger hole diameter in an existing manufacture line of the Si device.

However, the SiC substrate applied to the Si substrate with a larger hole diameter is required to be peeled from the Si substrate with a larger hole diameter during or after the process of manufacturing an element such as an IC chip and an LSI chip. Japanese Patent Application Laid-Open No. 11-87200 does not describe a method for peeling the SiC substrate from the Si substrate.

### OBJECTS OF THE INVENTION

The present invention has been made in view of the above problems, and it is an object of the present invention to provide a method for manufacturing a semiconductor device in which an SiC substrate is peeled from a lamination substrate, in which the SiC substrate is applied to an Si substrate or the like, without damaging an element such as an IC chip and an LSI chip formed on the surface of the SiC substrate, whereby a semiconductor device (SiC device) using SiC crystal is manufactured.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

In order to achieve the above object, a method for manufacturing a semiconductor device of the present invention includes an immersion process of immersing, in a fluoronitric acid solution, a lamination substrate in which an SiC substrate formed of a silicon carbide (SiC) single crystal is applied to a silicon substrate or a quartz substrate with a hole diameter larger than the SiC substrate and a peeling process of, after the silicon substrate or the quartz substrate is dissolved and removed from the fluoronitric acid solution, taking out the SiC substrate which is not dissolved and remains in the fluoronitric acid solution.

The above method for manufacturing a semiconductor device can further include, before the immersion step, a step of covering an exposed surface of the SiC substrate by a protective film which is not dissolved in the fluoronitric acid solution. Alternatively, the above method can further include, before the immersion step, a step of covering an exposed surface of the SiC substrate by a protective film which is not dissolved in the fluoronitric acid solution and a step of placing a transparent substrate or a transparent sheet, which is not dissolved in the fluoronitric acid solution, on the protective film so that the SiC substrate is sandwiched with the aid of the silicon substrate or the quartz substrate.

As the protective film which is not dissolved in the fluoronitric acid solution, a wax can be used. In addition, as the transparent substrate which is not dissolved in the fluoronitric acid solution, a sapphire substrate can be used. As the transparent sheet which is not dissolved in the fluoronitric acid solution, a polytetrafluoroethylene sheet can be used.

Further, the above method for manufacturing a semiconductor device can further include, after the peeling step, a step of dicing the SiC substrate into individual chips.

According to a method for manufacturing a semiconductor device in this invention, there is an effect that an SiC substrate which is applied to an Si substrate in a lamination substrate is peeled from the lamination substrate without damaging an element such as an IC chip and an LSI chip formed on the surface of the SiC substrate, whereby an semiconductor device (SiC device) using SiC crystal can be manufactured.

### BRIEF DESCRIPTION OF THE DRAWINGS

FIG. 1A is a front side plan view of a lamination substrate;

FIG. 1B is a cross-sectional view along a line A-A shown in FIG. 1A;

FIGS. 2A to 2D are schematic views showing an example of a manufacturing process of the lamination substrate;

FIGS. 3A and 3B are views showing that the lamination substrate is placed on a work table, FIG. 3A is a top plan view of the work table, and FIG. 3B is a side plan view of the front side of the work table;

FIGS. 4A and 4B are views showing a “coating process” for coating a wax, FIG. 4A is a side plan view showing that the wax is coated on an SiC wafer 12 placed on the work table, and FIG. 4B is a top plan view of the state shown in FIG. 4A;

FIGS. 5A and 5B are views showing a “placement process” for placing a transparent substrate on the lamination substrate, FIG. 5A is a side plan view showing that the transparent substrate is placed, and FIG. 5B is a top plan view of the state shown in FIG. 5A;

FIG. 6 is a view showing an “immersion process” for immersing the lamination substrate in a fluoronitric acid solution;

FIG. 7 is a view showing a “peeling process” for taking out the SiC wafer peeled from an Si wafer;

FIG. 8 is a plan view of the SiC wafer as viewed from the front surface (element-formed surface); and

FIG. 9 is a view showing that the SiC wafer is diced into individual chips.

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present invention is defined only by the appended claims.

Hereinafter, an example of an embodiment of the present invention is described in detail with reference to the drawings.

### <Laminated Type Semiconductor Substrate>

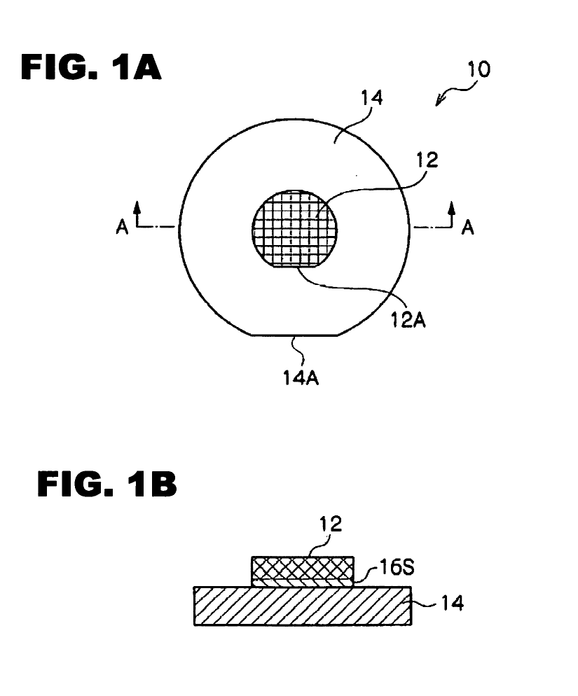

First, the constitution of a laminated type semiconductor substrate (hereinafter referred to as “lamination substrate”) manufactured in the embodiment of this invention is described. FIG. 1A is a front side plan view of the lamination substrate. FIG. 1B is a cross-sectional view along a line A-A shown in FIG. 1A. As shown in FIG. 1A, in a lamination substrate 10, a substrate (SiC wafer) 12 which is formed of a silicon carbide single crystal and has a small hole diameter is applied to a substantially central part of a silicon substrate (Si wafer) 14 with a hole diameter larger than the SiC wafer 12.

The SiC wafer 12 has a disk-like shape and has on the outer edge an orientation flat 12A. The orientation flat 12A is a linear cutout provided in order to show “crystal orientation”. The Si wafer 14 also has a disk-like shape and has on the outer edge an orientation flat 14A. The orientation flat 12A of the Sic wafer 12 is aligned so as to be parallel to the orientation flat 14A of the Si wafer 14 and applied to the Si wafer 14.

An SiC single crystal ingot is formed of silicon and carbon by using a sublimation method to be sliced, whereby the SiC wafer 12 can be obtained. It is so difficult to increase the hole diameter of the SiC wafer 12 that only wafer with a hole diameter of 2 to 3 inch (diameter is 50 to 75 mm) can be obtained at present. In the example of this embodiment, the SiC wafer 12 with a hole diameter of 2 inch (diameter of 50 mm) and a thickness of 350 μm is used.

Polycrystalline silicon is melted in an electric furnace, and an Si single crystal ingot is pulled from a melt by the Czochralski method to be sliced into a thickness of 300 μm to 2 mm, whereby the Si wafer 14 can be obtained. The wafer with a hole diameter of 5 to 8 inch (diameter is 125 to 200 mm) is mostly used as the Si wafer 14 at present. In the example of this embodiment, the Si wafer 14 with a hole diameter of 6 inch (diameter of 150 mm) and a thickness of 625 μm is used.

As shown in FIG. 1B, the SiC wafer 12 is adhered to the Si wafer 14 through an SOG solidified film 16S. The SOG solidified film 16S is a heat-resistant silica-based coating film formed by a spin-on glass (SOG) method. The SOG solidified film 16S has at least a heat resistance of 400° C. or higher. The SOG solidified film 16S is subjected to a high-temperature heat processing, whereby the heat resistance can be increased to close to 1000° C.

In the SOG method, a coating solution in which alkoxysilane is dissolved in the solvent is applied onto a base material, and thereafter to be subjected to heating treatment, and, thus, to be solidified by the dehydration condensation reaction of alkoxysilane, whereby the silica-based coating film is formed. In the SOG coating solution, alkoxysilane, which uses silicon-oxygen (Si—O) combination as the framework and contains silanol group (—Si—OH), is dissolved in an organic solvent which is vaporized at about 300° C. The heat treatment is performed under pressure, whereby the organic solvent remaining in an SOG coating film is removed, and the SOG coating film is solidified to become an SOG solidified film 16S. The SiC wafer 12 is firmly and closely fixed to the Si wafer 14 through the SOG solidified film 16S.

### <Method for Manufacturing Lamination Substrate>

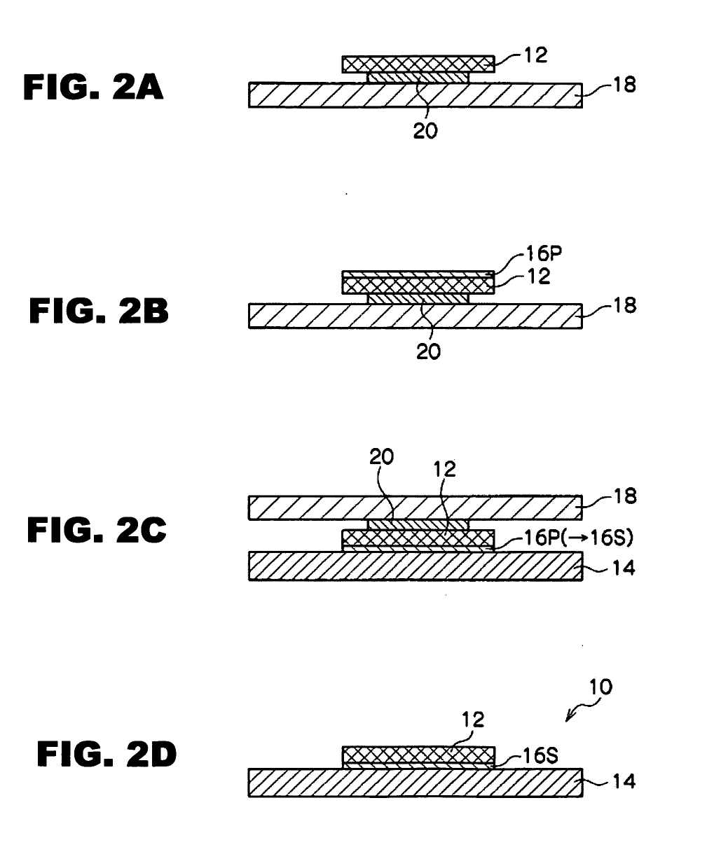

FIGS. 2A to 2D are schematic views showing an example of a manufacturing process of the lamination substrate. The outline of the manufacturing process is briefly explained with reference to the drawings. Although the orientation flat is not illustrated, the orientation flat is provided in each wafer as above mentioned.

First, in a “temporal fixation process” shown in FIG. 2A, the SiC wafer 12 is temporarily fixed to an Si wafer 18, which is different from the Si wafer 14, through a heat-stable wax 20. The Si wafer 18 has the same hole diameter as the Si wafer 14. The Si wafer 18 has an orientation flat 18A provided at the same position as the orientation flat 14A of the Si wafer 14. The SiC wafer 12 is precisely aligned so that the orientation flat 12A becomes parallel to the orientation flat 18A to be temporarily fixed to the Si wafer 18.

In the temporal fixation process, the front surface of the SiC wafer 12 to be subjected to various processings is temporarily fixed to the Si wafer 18 through the wax 20. The wax 20 used for the temporal fixation is fused when heated to above the melting point, and therefore, the SiC wafer 12 can be moved and detached. Therefore, the position of the SiC wafer 12 can be repeatedly adjusted on the Si wafer 18 until the precise alignment of the SiC wafer 12 is performed. In addition, the wax 20 protects the surface of the SiC wafer 12 from damages, such as scratches, particles (adhesion of dusts), and contamination.

Second, in an “application process” shown in FIG. 2B, an SOG coating solution is applied onto the SiC wafer 12, which is temporarily fixed to the Si wafer 18, to form an SOG film 16P on the rear surface side of the SiC wafer 12. Third, in an “adhesion process” shown in FIG. 2C, the SiC wafer 12 temporarily fixed to the Si wafer 18 is superposed with the Si wafer 14 through the SOG film 16P. The orientation flats 14A and 18A are aligned with each other, whereby the Si wafers 14 and 18 having the same hole diameter are easily superposed with each other.

Heating is performed under pressure in such a state that the Si wafer 14 and the Si wafer 18 are superposed with each other to solidify the SOG film 16P, and, thus, to form the SOG solidified film 16S. The SiC wafer 12 is adhered to the Si wafer 14 through the SOG solidified film 16S. The SiC wafer 12 temporarily fixed to the predetermined position of the Si wafer 18 is adhered to the predetermined position of the Si wafer 14 facing the Si wafer 18 so as to be transferred from the Si wafer 18 to the Si wafer 14. If the alignment of the SiC wafer 12 is precisely performed in the process of temporarily fixing the SiC wafer 12 to the Si wafer 18, the SiC wafer 12 is precisely transferred to a predetermined position of the Si wafer 14.

Fourth, in a “removal process” shown in FIG. 2D, the Si wafer 18 to which the SiC wafer 12 is temporarily fixed is detached. In addition, the unneeded wax 20 is removed. According to the constitution shown in FIGS. 2A to 2D, the lamination substrate 10 in which the SiC wafer 12 with a small hole diameter is applied to a substantially central part of the Si wafer 14 with a larger hole diameter can be easily obtained. The SiC wafer 12 is precisely transferred to the predetermined position of the Si wafer 14, and therefore, the orientation flat 12A of the SiC wafer 12 becomes parallel to the orientation flat 14A of the Si wafer 14 (see, FIG. 1A). Thus, the crystal orientation of the SiC wafer 12 can be judged from the orientation flat 14A of the Si wafer 14.

### <Method for Peeling SiC Substrate>

The SiC wafer 12 applied to the Si wafer 14 is processed in an existing manufacture line for an Si device in a similar manner to the Si wafer 14 with a larger hole diameter, and an element constituting an IC chip, an LSI chip, and so on is formed on the surface of the Si wafer 14. After the process of manufacturing such an element constituting an IC chip, an LSI chip, and so on is terminated, the SiC wafer 12 is required to be peeled from the Si wafer 14 with a larger hole diameter.

In a wafer processing process with respect to the SiC wafer 12, in an impurity introduction process, although ion-implantation activation heat treatment is performed at a temperature of 1300° C. or higher (normally, about 1600° C.), the lamination substrate 10 cannot be processed as it is. In this case, the SiC wafer 12 is temporarily removed from the Si wafer 14 during the element manufacturing process, and the SiC wafer 12 is required to be applied again to the Si wafer 14 after the impurity introduction process.

In this invention, in order to peel the SiC wafer 12 from the Si wafer 14, the lamination substrate 10 is immersed in a fluoronitric acid solution. The fluoronitric acid solution is a mixed solution which contains at least hydrogen fluoride (HF) and nitric acid (HNO₃) and according to need, contains water and acetic acid. In general, the same amount of 50% (% by weight) hydrofluoric acid solution and nitric acid are mixed to prepare the fluoronitric acid solution. In this case, the ratio among hydrogen fluoride, nitric acid, and water is about 3:5:2. Although the Si wafer 14 is easily dissolved in the fluoronitric acid solution, the SiC wafer 12 is not dissolved in the fluoronitric acid solution. The SOG solidified film 16S is also easily dissolved in the fluoronitric acid solution. Therefore, only the SiC wafer 12 which is not dissolved in the fluoronitric acid solution remains in the fluoronitric acid solution, whereby the SiC wafer 12 can be easily peeled.

However, when an element is formed on the SiC wafer 12 after the element manufacturing process, and when various films are already formed on the SiC wafer 12 during the element manufacturing process, in order to prevent the element and films from being eroded by the fluoronitric acid solution, it is preferable that the surface of the SiC wafer 12 is previously coated with a protective film to protect the element and films.

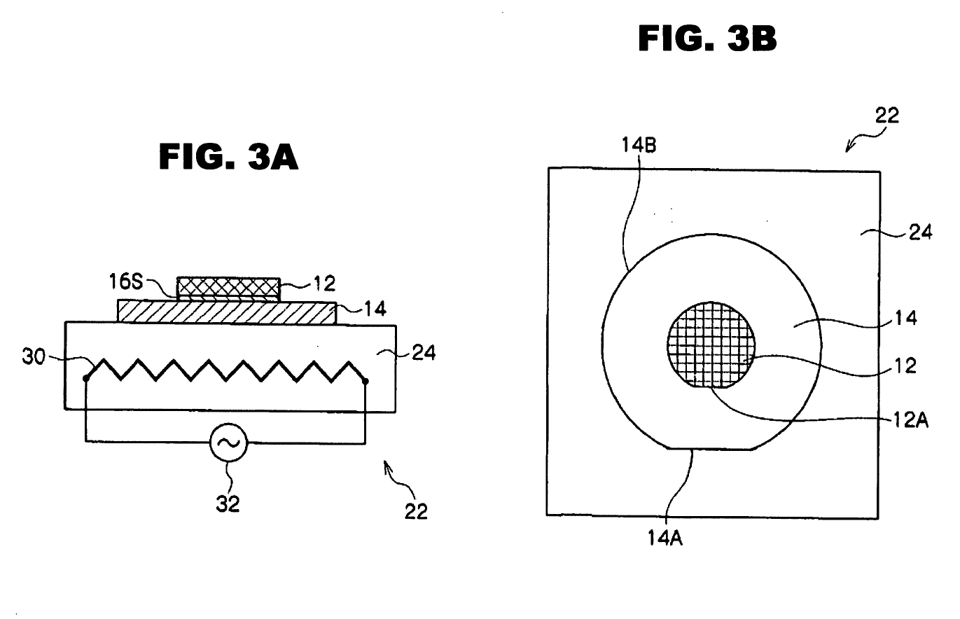

Next, a manufacturing process (process for peeling the SiC substrate) according to the embodiment of this invention is described in detail with reference to FIGS. 3 to 8. This manufacturing process includes a “pretreatment process” in which pretreatment is performed before the lamination substrate 10 is immersed in the fluoronitric acid solution, an “immersion process” for immersing the lamination substrate 10 in the fluoronitric acid solution, and a “peeling process” of taking out the SiC wafer 12 which is not dissolved and remains in the fluoronitric acid solution. The “pretreatment process” can be omitted in accordance with the stage of the element manufacturing process for example when a film eroded by the fluoronitric acid solution is not formed on the surface.

### (Pretreatment Process)

The manufacturing process according to this embodiment includes a “pretreatment process” including a “coating process” for coating an exposed surface of the SiC wafer 12 by a protective film (for example, a wax 19 to be described below) which is not dissolved in the fluoronitric acid solution and a “placement process” for placing a transparent substrate (for example, a sapphire substrate 21 to be described below), which is not dissolved in the fluoronitric acid solution, on the protective film, so that the SiC wafer 12 is sandwiched between the transparent substrate and the Si wafer 14.

FIG. 3 shows that the lamination substrate 10 is placed on a work table. FIG. 3A is a top plan view of the work table. FIG. 3B is a side plan view of the front side of the work table.

As shown in FIG. 3A, a work table 22 has a plate 24 which has a rectangular shape as viewed from the above. The Si wafer 14 with the SiC wafer 12 applied thereto is placed on the plate 24 of the work table 22. As shown in FIG. 3B, the plate 24 has a resistance heating heater 30 built therein. The resistance heating heater 30 is connected to an AC source 32. The temperature of the plate 24 can be increased until about 600° C. by the resistance heating heater 30 built in the plate 24. The On and off and temperature adjustment of the resistance heating heater 30 can be realized by a switch (not shown).

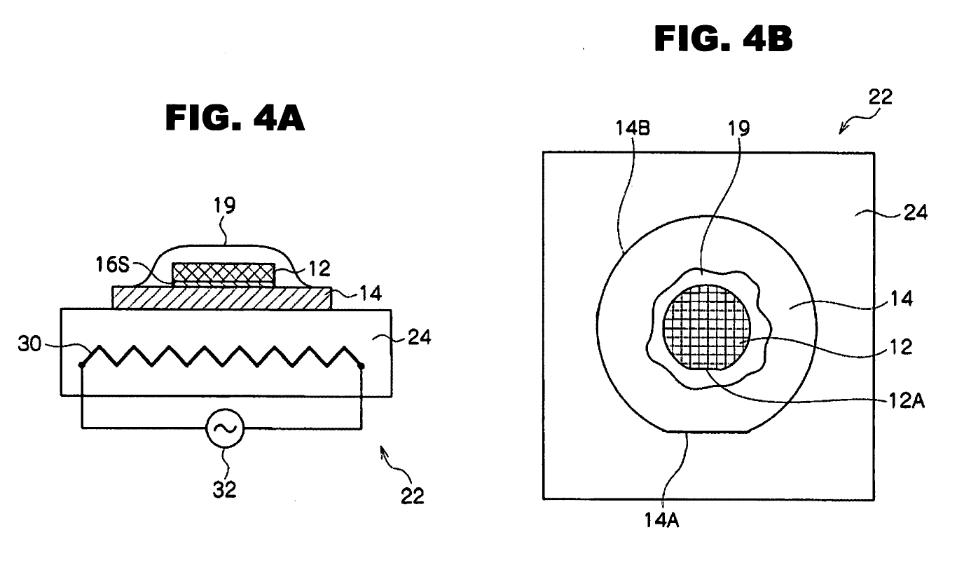

FIG. 4 shows a “coating process” for coating a wax. FIG. 4A is a side plan view showing that the wax is coated on the SiC wafer 12 placed on the work table. FIG. 4B is a top plan view of the state shown in FIG. 4A.

As shown in FIGS. 4A and 4B, the lamination substrate 10 placed on the work table 22 is heated by the resistance heating heater 30. In this embodiment, the heat-stable wax 19 is coated near the center of the lamination substrate 10 so as to cover the heated SiC wafer 12 in such a state that the lamination substrate 10 is heated at 180° C. The wax 19 is somewhat thickly coated so that, when the work table 22 is viewed from the above, the wax 19 is protruded from the SiC wafer 12. As the degree of the protrusion, the wax 19 is coated to have a width with sufficient margin with respect to the corrosive property of the fluoronitric acid solution against the wax and the depth in which the fluoronitric acid solution is penetrated along the interface between the wax 19 and the Si wafer 14.

As the wax 19 as a protective film which is not dissolved in the fluoronitric acid solution, a wax, which has an upper temperature limit higher than the vaporization temperature of an organic solvent contained in the SOG coating solution, is used. In this embodiment, the wax which has a melting point of about 150° C. and is not transmuted even at about 350° C. is used.

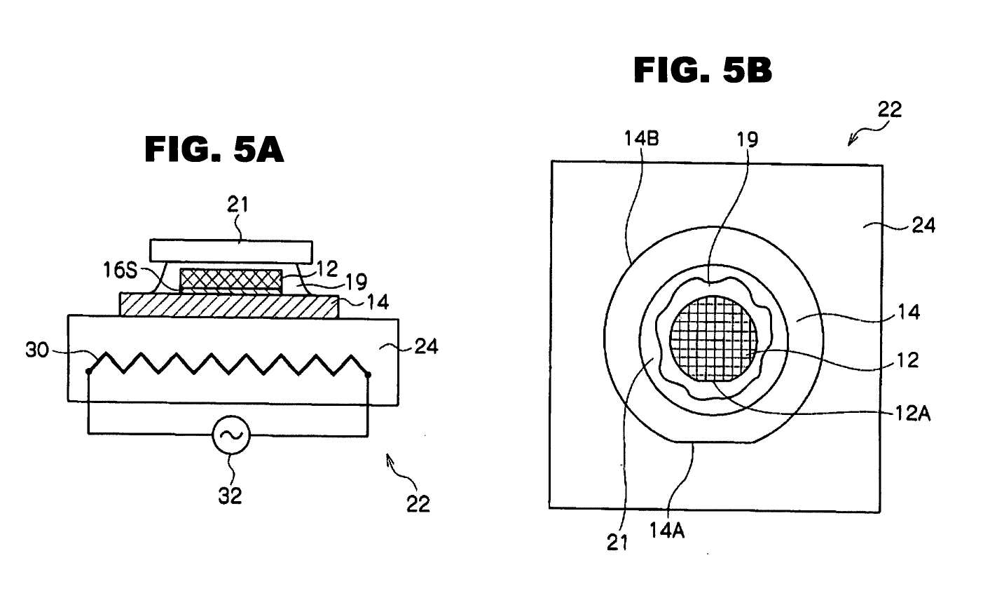

FIG. 5 shows a “placement process” for placing a transparent substrate (sapphire substrate 21) on the lamination substrate 10. FIG. 5A is a side plan view showing a state in which the transparent substrate is placed, and FIG. 5B is a top plan view of the state shown in FIG. 5A.

As shown in FIGS. 5A and 5B, the sapphire substrate 21 as a transparent substrate which is not dissolved in the fluoronitric acid solution is placed on the wax 19 coated onto the lamination substrate 10. The sapphire substrate 21 is placed on a substantially center of the lamination substrate 10. The lamination substrate 10 remains heated at 180° C. by the resistance heating heater 30, and the wax 19 is fused, and therefore, the sapphire substrate 21 is placed on the wax 19 so that the wax 19 is flattened (covered). The wax 19 spreads thinly between the sapphire substrate 21 and the SiC wafer 12.

Thereafter, the resistance heating heater 30 is turned off to decrease the temperature of the plate 24, and the entirety of the SiC wafer 12, the Si wafer 14, the SOG film 16S, the wax 19, and the sapphire substrate 21 is cooled, whereby the wax 19 is solidified to fix the sapphire substrate 21. The cooled lamination substrate 10 is removed from the work table, whereby the “pretreatment process” is completed.

### (Immersion Process)

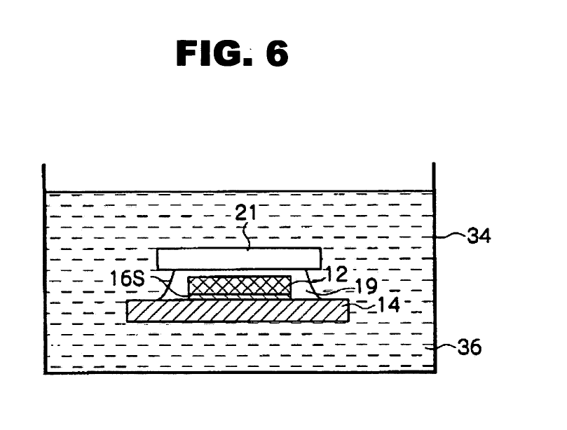

FIG. 6 shows an “immersion process” for immersing the lamination substrate 10 in the fluoronitric acid solution. As shown in FIG. 6, in the lamination substrate 10, the SiC wafer 12 is covered with the wax 19, and the sapphire substrate 21 is immersed in a fluoronitric acid solution 36 filled in an immersion vessel 34 in the state of being placed on the wax 19.

The Si wafer 14 and the SOG solidified film 16S are gradually dissolved in the fluoronitric acid solution 36. Meanwhile, the SiC wafer 12, the wax 19, and the sapphire substrate 21 are not dissolved in the fluoronitric acid solution 36. However, in some cases, the surface of the wax 19 may be partially eroded by the fluoronitric acid solution 36 to cause a haze. In addition, the fluoronitric acid solution 36 penetrates along the interface between the wax 19 and the Si wafer 14.

In the immersion process, the state of the SiC wafer 12 applied to the Si wafer 14 can be clearly observed through the transparent sapphire substrate 21. Namely, the penetration of the fluoronitric acid solution 36 can be clearly confirmed from the periphery of the wax 19. Thus, it is possible to prevent the fluoronitric acid solution 36 from reaching the SiC wafer 12 to erode the element formed on the surface of the SiC wafer 12. For example, when the penetration of the fluoronitric acid solution 36 is fast, the immersion process is immediately stopped, and the wax is then applied again, whereby the element formed on the surface of the SiC wafer 12 is prevented from being eroded.

When the Si wafer 14 and the SOG solidified film 16S are completely dissolved in the fluoronitric acid solution 36, the “immersion process” is terminated. After the termination of “immersion process”, the SiC wafer 12, the wax 19, and the sapphire substrate 21 which are not dissolved in the fluoronitric acid solution 36 remain in the fluoronitric acid solution 36.

### (Peeling Process)

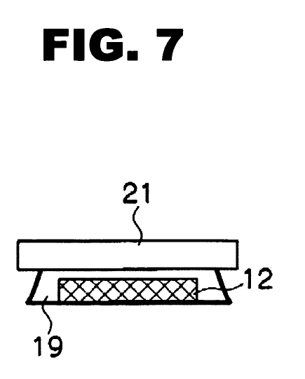

FIG. 7 shows a “peeling process” for taking out the SiC wafer 12 peeled from the Si wafer 14. As shown in FIG. 7, the SiC wafer 12, the wax 19, and the sapphire substrate 21 which are not dissolved and remain in the fluoronitric acid solution 36 are taken out from the in the fluoronitric acid solution 36, whereby the “peeling process” for peeling the SiC wafer 12 from the Si wafer 14 is terminated.

### (Other Process)

After the termination of the peeling process, the wax 19 adhered around the SiC wafer 12 is removed. The sapphire substrate 21 is removed together with the wax 19. The wax 19 is removed by organic cleaning using an organic solvent such as acetone. According to this constitution, only the SiC wafer 12 can be obtained. Incidentally, when a wiring layer which is not activated yet is not provided, the wax can be removed by inorganic cleaning using sulfuric acid and hydrogen peroxide solution on an exceptional basis.

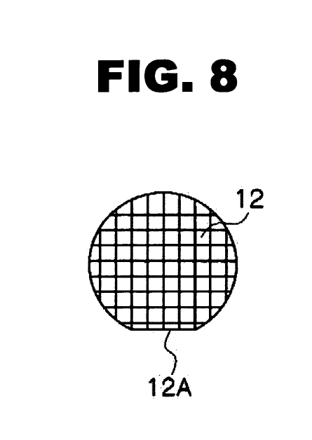

FIG. 8 is a plan view of the SiC wafer 12 as viewed from the front surface (element-formed surface). As shown in FIG. 8, a grid-like pattern for alignment is previously formed on the surface of the SiC wafer 12. The grid-like pattern is constituted of plural straight lines drawn at a predetermined interval in parallel with the orientation flat 12A and plural straight lines drawn at a predetermined interval in perpendicular to the orientation flat 12A. The element such as an IC chip and an LSI chip is formed in each grid.

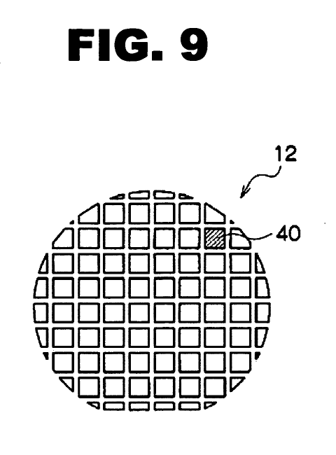

Thus, when the element such as an IC chip and an LSI chip is already formed, as shown in FIG. 9, a blade (not shown) is moved along the straight line of the grid-like pattern before the SiC wafer 12 is peeled from the Si wafer 14, and the SiC wafer 12 is saw cut into a grid-like shape, whereby the SiC wafer 12 can be diced into individual chips 40. As the blade, a diamond blade or the like can be used.

As above described, in this embodiment, the SiC wafer (lamination substrate) applied to the Si wafer with a larger hole diameter is processed in an existing manufacture line for an Si device in a similar manner to the Si wafer with a larger hole diameter, and during or after the element manufacturing process for an IC chip, an LSI chip, and so on, the SiC wafer is peeled from the Si wafer with a larger hole diameter.

The SiC wafer is peeled by a method of immersing the lamination substrate in the fluoronitric acid solution which dissolves the Si wafer but does not dissolve the SiC wafer. According to this method, in comparison with the case in which the SiC wafer is peeled by applying a physical force, the SiC wafer can be easily peeled from the lamination substrate without damaging the element such as an IC chip and an LSI chip formed on the surface of the SiC wafer.

In addition, in this embodiment, the surface of the SiC wafer is covered by the protective film such as a wax, and therefore, also in the immersion process, the already formed element and films are not eroded by the fluoronitric acid solution.

Further, in this embodiment, the transparent sapphire substrate is further stacked on the wax, and in the immersion process, since the state of the SiC wafer applied to the Si wafer can be clearly observed through the transparent sapphire substrate, the penetration of the fluoronitric acid solution can be clearly confirmed, whereby the element formed on the surface of the SiC wafer can be prevented from being eroded by the fluoronitric acid solution.

### <Variation>

### (Large Diameter Substrate)

In this embodiment, although a silicon substrate is used as a large hole diameter substrate to which an SiC substrate will be applied, a quartz substrate can be used instead of the silicon substrate. The quartz substrate is easily dissolved in the fluoronitric acid solution, and therefore, the SiC substrate can be easily peeled by a similar method.

### (Transparent Substrate and Transparent Sheet)

Further, in this embodiment, the sapphire substrate is used as the transparent substrate placed on the wax; however, if the transparent substrate is not dissolved in the fluoronitric acid solution, the transparent substrate is not limited especially, and not only an inorganic material but also an organic material can be used. For example, a plastic substrate (or sheet) such as a polytetrafluoroethylene sheet which is well-known as “Teflon (registered trademark)” can be used as a substitute for the transparent substrate.

What is claimed is:

1. A method for manufacturing a semiconductor device comprising:
immersing, in a fluoronitric acid solution, a lamination substrate, in which an SiC substrate formed of a silicon carbide (SiC) single crystal is applied to a silicon substrate or a quarts substrate with a larger hole diameter than the SiC substrate; and
removing the SiC substrate which is not dissolved and remains in the fluoronitric acid solution after the silicon substrate or the quartz substrate is dissolved and removed from the fluoronitric acid solution.

2. The method for manufacturing a semiconductor device according to claim 1, further comprising:
before the immersion step, covering an exposed surface of the SiC substrate by a protective film which is not dissolved in the fluoronitric acid solution.

3. The method for manufacturing a semiconductor device according to claim 1, further comprising:
before the immersion step, covering an exposed surface of the SiC substrate by a protective film which is not dissolved in the fluoronitric acid solution and a step of placing a transparent substrate or a transparent sheet, which is not dissolved in the fluoronitric acid solution, on the protective film so that the SiC substrate is sandwiched between the transparent substrate and the silicon substrate or the quartz substrate.

4. The method for manufacturing a semiconductor device according to claim 2, wherein
the protective film which is not dissolved in the fluoronitric acid solution is a wax.

5. The method for manufacturing a semiconductor device according to claim 3, wherein
the transparent substrate which is not dissolved in the fluoronitric acid solution is a sapphire substrate.

6. The method for manufacturing a semiconductor device according to claim 3, wherein
the transparent sheet which is not dissolved in the fluoronitric acid solution is a polytetrafluoroethylene sheet.

7. The method for manufacturing a semiconductor device according to claim 1, further comprising:
after removing the SiC substrate, dicing the SiC substrate into individual chips.
